(19) United States
(12) Patent Application Publication
(10) Pub. No.: US 2014/0061792 A1
(43) Pub. Date: Mar. 6, 2014

(54) FIELD EFFECT TRANSISTOR DEVICES WITH RECESSED GATES

(71) Applicants: Huiming Bu, Millwood, NY (US); Terence B. Hook, Jericho, VT (US); Reinaldo A. Vega, Wappingers Falls, NY (US)

(72) Inventors: Huiming Bu, Millwood, NY (US); Terence B. Hook, Jericho, VT (US); Reinaldo A. Vega, Wappingers Falls, NY (US)

(73) Assignee: INTERNATIONAL BUSINESS MACHINES CORPORATION, Armonk, NY (US)

(21) Appl. No.: 13/596,409

(22) Filed: Aug. 28, 2012

(51) Int. Cl. H01L 29/78; H01L 29/786

(52) U.S. Cl. 257/347; 257/401; 257/E29.255; 257/E29.273

(57) ABSTRACT

A field effect transistor device includes a bulk semiconductor substrate, a fin arranged on the bulk semiconductor substrate, the fin including a source region, a drain region, and a channel region, a first shallow trench isolation (STI) region arranged on a portion of the bulk semiconductor substrate adjacent to the fin, a first recessed region partially defined by the first STI region and the channel region of the fin, and a gate stack arranged over the channel region of the fin, wherein a portion of the gate stack is partially disposed in the first recessed region.

### BACKGROUND

The present invention relates to field effect transistor devices, and more specifically, to field effect transistor devices having recessed gates.

Field effect transistor (FET) devices include a source region, drain region, and a channel region disposed therebetween. Multi-gate devices such as, for example FinFET devices include a fin formed on a substrate that defines a channel region having a gate stack arranged over the fin.

### SUMMARY

According to one embodiment of the present invention, a field effect transistor device includes a bulk semiconductor substrate, a fin arranged on the bulk semiconductor substrate, the fin including a source region, a drain region, and a channel region, a first shallow trench isolation (STI) region arranged on a portion of the bulk semiconductor substrate adjacent to the fin, a first recessed region partially defined by the first STI region and the channel region of the fin, and a gate stack arranged over the channel region of the fin, wherein a portion of the gate stack is partially disposed in the first recessed region.

According to another embodiment of the present invention, a field effect transistor device includes a bulk semiconductor substrate, a fin arranged on the bulk semiconductor substrate, the fin including a source region, a drain region, and a channel region, a first shallow trench isolation (STI) region arranged on a portion of the bulk semiconductor substrate adjacent to the fin, a first recessed region partially defined by the first STI region and the channel region of the fin, the first recessed region including a bottom surface and opposing sidewalls arranged adjacent to the bottom surface, each opposing sidewall defining an oblique angle with the bottom surface, and a gate stack arranged over the channel region of the fin, wherein a portion of the gate stack is partially disposed in the first recessed region.

According to yet another embodiment of the present invention, a field effect transistor device includes a silicon-on-insulator (SOI) substrate an insulator layer, a fin arranged on the insulator layer, the fin including a source region, a drain region, and a channel region, a first recessed region partially defined by the insulator layer and the channel region of the fin, and a gate stack arranged over the channel region of the fin, wherein a portion of the gate stack is partially disposed in the first recessed region.

Additional features and advantages are realized through the techniques of the present invention. Other embodiments and aspects of the invention are described in detail herein and are considered a part of the claimed invention. For a better understanding of the invention with the advantages and the features, refer to the description and to the drawings.

### BRIEF DESCRIPTION OF THE SEVERAL VIEWS OF THE DRAWINGS

The subject matter which is regarded as the invention is particularly pointed out and distinctly claimed in the claims at the conclusion of the specification. The forgoing and other features, and advantages of the invention are apparent from the following detailed description taken in conjunction with the accompanying drawings in which:

FIG. 1 illustrates a perspective view of a prior art example of a FinFET device.

FIG. 2 illustrates a perspective view of an exemplary embodiment of a FET device.

FIG. 3 illustrates a front view of the device of FIG. 2.

FIG. 4 illustrates a cut-away view of the device along the line 4 of FIG. 2.

FIG. 5 illustrates a perspective view of an alternate embodiment of a FET device.

FIG. 6 illustrates a front view of the device of FIG. 5.

FIG. 7 illustrates a cut-away view of the device along the line 7 of FIG. 5.

FIG. 8 illustrates another alternate embodiment of a FET device.

FIG. 9 illustrates a front view of the device of FIG. 8.

FIG. 10 illustrates a cut-away view of the device along the line 10 of FIG. 8.

FIG. 11 illustrates a cut-away view of the device along the line 11 of FIG. 8.

FIG. 12 illustrates a cut-away view of the device along the line 12 of FIG. 8.

FIG. 13 illustrates a perspective view of another alternate embodiment of a FET device.

### DETAILED DESCRIPTION

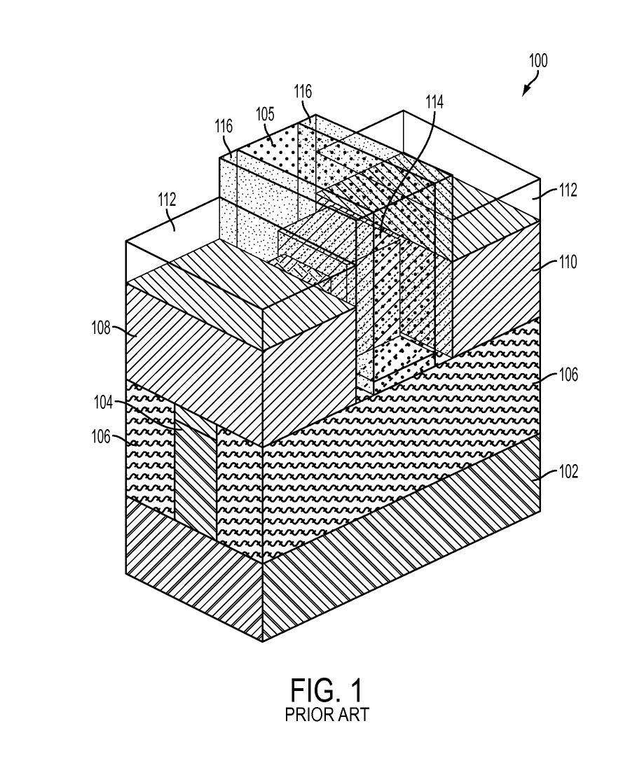

FIG. 1 illustrates a perspective view of a prior art example of a FinFET device 100. The device 100 is arranged on a bulk silicon substrate 102. A fin 104 is arranged on the substrate 102. Shallow trench isolation (STI) regions 106 are arranged on the substrate 102 and adjacent to the fin 104. Source and drain regions 108 and 110 are arranged over the fin 104. The source and drain regions 108 and 110 may include, for example, a doped epitaxially grown silicon material that is grown from portions of the fin 104. A silicide material 112 is arranged on the source and drain regions 108 and 110. A gate stack 114 is arranged over a channel region of the fin 104 and a portion of the STI regions 106. Spacers 116 are arranged adjacent to the gate stack 114. The device 100 may exhibit undesirable source-to-drain leakage current. A conductive contact layer 105 may be arranged over the gate stack 114.

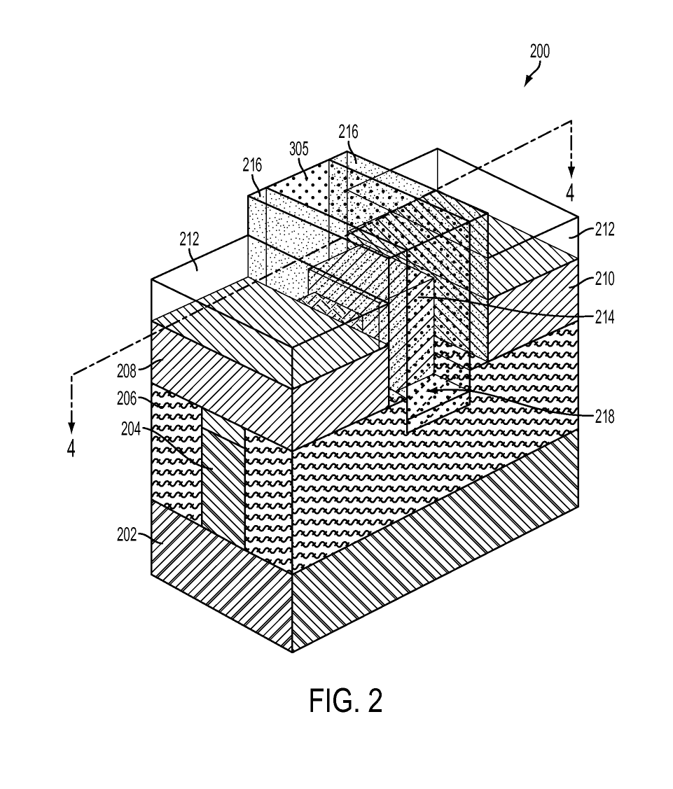

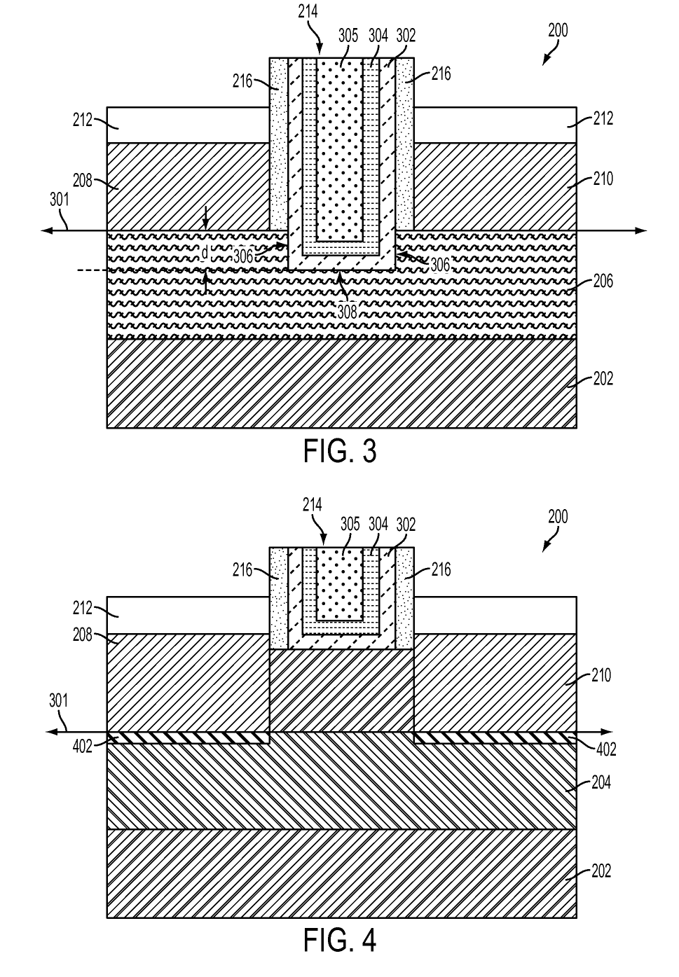

FIG. 2 illustrates a perspective view of an exemplary embodiment of a FET device 200. In this regard, the device 200 is arranged on a bulk substrate 202 that may include, for example, a semiconductor material such as, a silicon or a germanium material. A fin 204 is arranged on the substrate 102, and may be formed from a material similar to the substrate 102 material. STI regions 206 are arranged on the substrate 102 and adjacent to the fin 204. The STI regions 206 may include, for an insulator material such as, for example, an oxide or nitride material. A source region 208 and a drain region 210 are arranged over portions of the fin 204 and the STI regions 206. The source and drain regions 208 and 210 may include, for example, a doped semiconductor material such as silicon or germanium. Silicide regions 212 are arranged on the source and drain regions 208 and 210. A gate stack 214 is arranged over a channel region of the fin 204. The gate stack 214 may include, for example, a dielectric material layer disposed over the fin 204 and a gate conductor layer arranged over the dielectric material layer (each described below). Spacers 216 may be arranged adjacent to the gate stack 214. The spacers 216 may include one or more materials such as, for example, oxide or nitride materials. The STI regions 206 and the fin 204 define recessed regions 218 on opposing sides of, and adjacent to the channel region of the fin 204. The gate stack 214 conforms to opposing sides of the fin 204 and extends into the recessed regions 218. In some embodiments, portions of the gate stack 214 may conform to the opposing facing sides of the spacers 216 (As not shown in FIG. 2 for illustrative clarity, but shown in FIG. 3). The source and drain regions 208 and 210 define a plane where the source and drain regions 208 and 210 contact the STI regions 206. The depth of the recessed regions 218 is below the plane such that the channel region of the fin 204 and the portions of the gate stack 214 arranged on the sides of the fin 204 extends below the source and drain regions 208. A conductive contact layer 305 may be arranged over the gate stack 214.

The FET device 200 described above increases the depth of the channel region of the device 200. Dopants may be added to the substrate 202 and/or fin 204 in the regions below the source and drain regions 208 and 210 to suppress source-to-drain leakage, however if the dopant concentrations are too high, junction leakage may be increased. The increase in the depth of the channel region of the device 200 facilitates a reduction in the doping of the substrate 202 and/or the fin 204 without undesirably increasing source-to-drain leakage.

FIG. 3 illustrates a front view of the device 200. In the illustrated embodiment, the gate stack 214 includes a dielectric layer 302 and a gate conductor layer 304. The dielectric layer 302 may include any suitable dielectric material including a high-K material. The gate conductor layer 304 may include any suitable gate conductor material such as for example, a polysilicon or metallic material. A conductive contact layer 305 may be arranged over the gate conductor layer 304. In this regard, the gate stack 214 may include a single gate conductor layer 304 that may provide a conductive gate contact similar to the layer 305, or the gate contact layer 305 may be arranged on the gate conductor layer 304. The conductive contact layer 305 may include, for example, a low resistance metallic material or a gate conductor material.

As discussed above, the source and drain regions 208 and 210 define a plane 301 where the source and drain regions 208 and 210 contact the STI regions 206. The recessed regions 218 partially defined by the STI regions 206 include sidewalls 306 and a bottom surface 308. The depth (d) is defined by the bottom surface 308 of the recessed regions 218 and the plane 301.

FIG. 4 illustrates a cut-away view of the device 200 along the line 4 of FIG. 2. In this regard, the device 200 includes regions 402 arranged in the fin 204 adjacent to the source and drain regions 208 and 210 that may include a concentration of dopants.

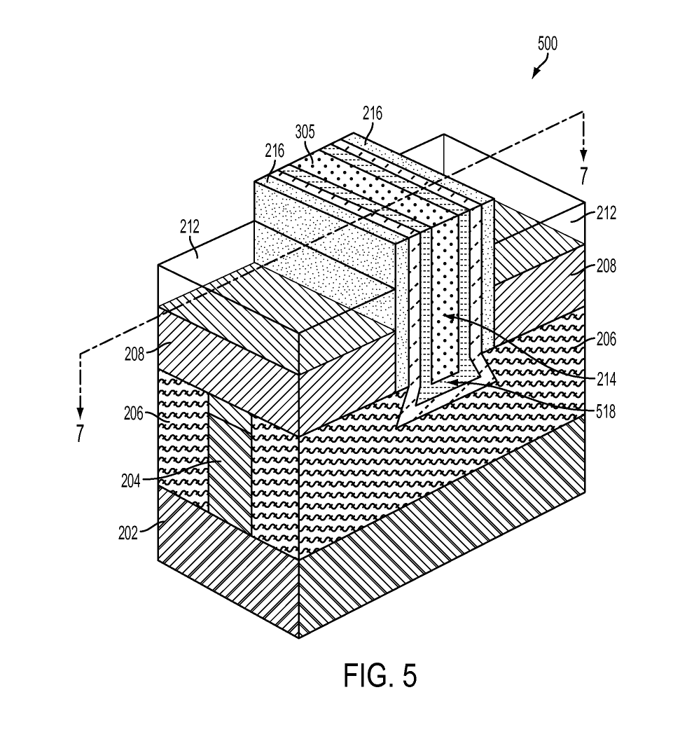

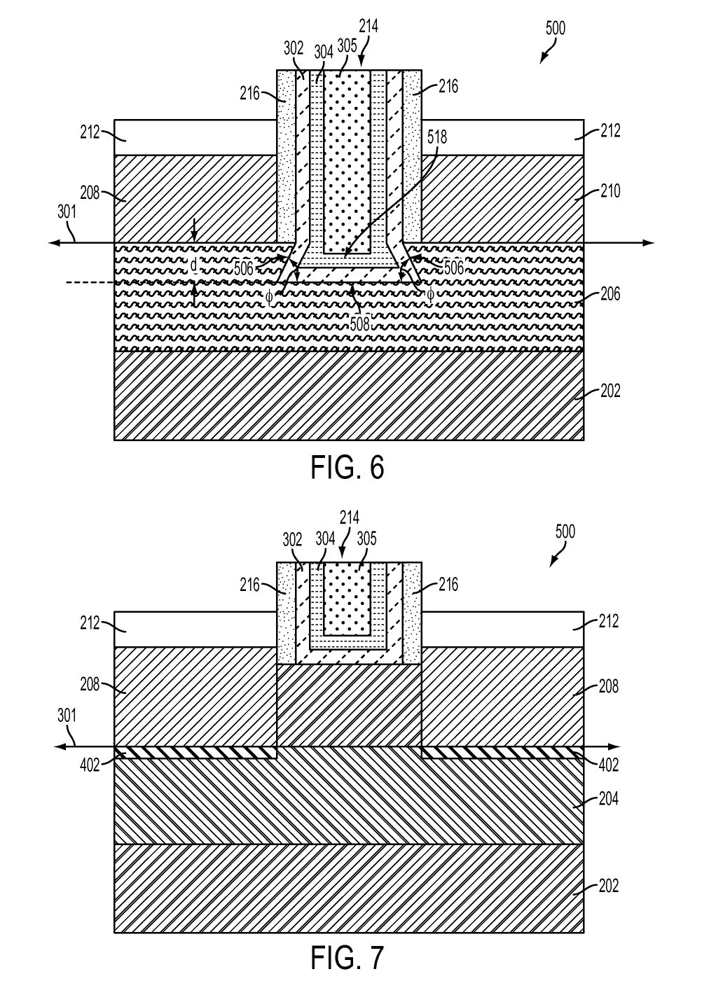

FIG. 5 illustrates a perspective view of an alternate embodiment of a FET device 500. In this regard, the device 500 is similar to the device 200 described above however, a recessed region 518 includes sloped sidewalls 506 (described below). In some embodiments, portions of the gate stack 214 may conform to the opposing facing sides of the spacers 216 (Not shown in FIG. 5 for illustrative clarity, but shown in FIG. 6).

FIG. 6 illustrates a front view of the device 500. The recessed region 518 includes sidewalls 506 that intersect the bottom surface 508. The sidewalls 506 are sloped at an oblique angle (φ) defined by the sidewalls 506 and the plane 301. The sloping of the sidewalls 506 provides an undercut region for the formation of a portion of the gate stack 214. The gate stack 214 thus, extends below portions of the source and drain regions 208 and 210, and provides a more uniform gate overlap with source and drain extension regions. FIG. 7 illustrates a cut-away view of the device 500 along the line 7 of FIG. 5. Though the illustrated embodiment includes sidewalls 506 having a substantially planar surface, alternate embodiments may include sidewalls having a curved or substantially elliptically shaped surface.

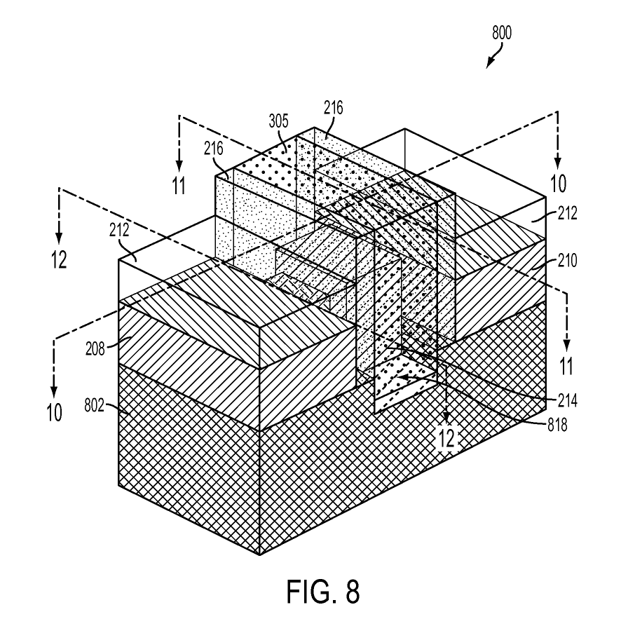

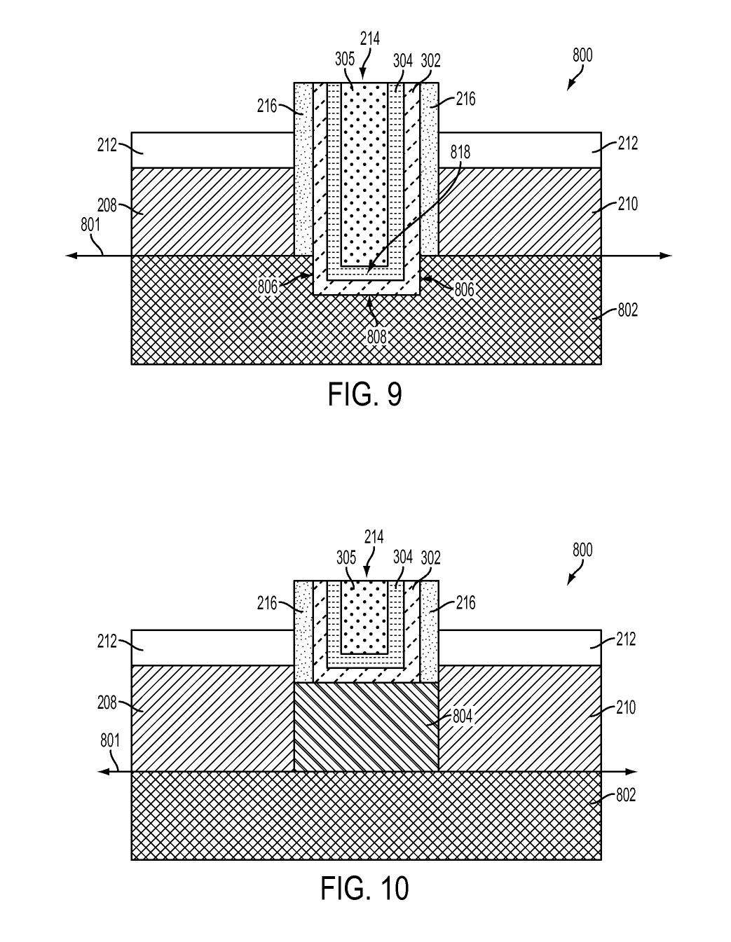

FIG. 8 illustrates another alternate embodiment of a FET device 800. In the illustrated embodiment, the FET device 800 is arranged on a silicon-on-insulator (SOI) substrate that includes an insulator layer 802 that may include, for example, an oxide material, and a silicon or semiconductor layer arranged on the insulator layer 802. The silicon layer in the illustrated embodiment has been formed into a fin of the device 800 (described below). The FET device 800 is similar to the exemplary embodiments of the FET devices described above however; the recessed region 818 is formed in the insulator layer 802 (as opposed to being formed in the STI regions as described above). In some embodiments, portions of the gate stack 214 may conform to the opposing facing sides of the spacers 216 (Not shown in FIG. 8 for illustrative clarity, but shown in FIG. 9).

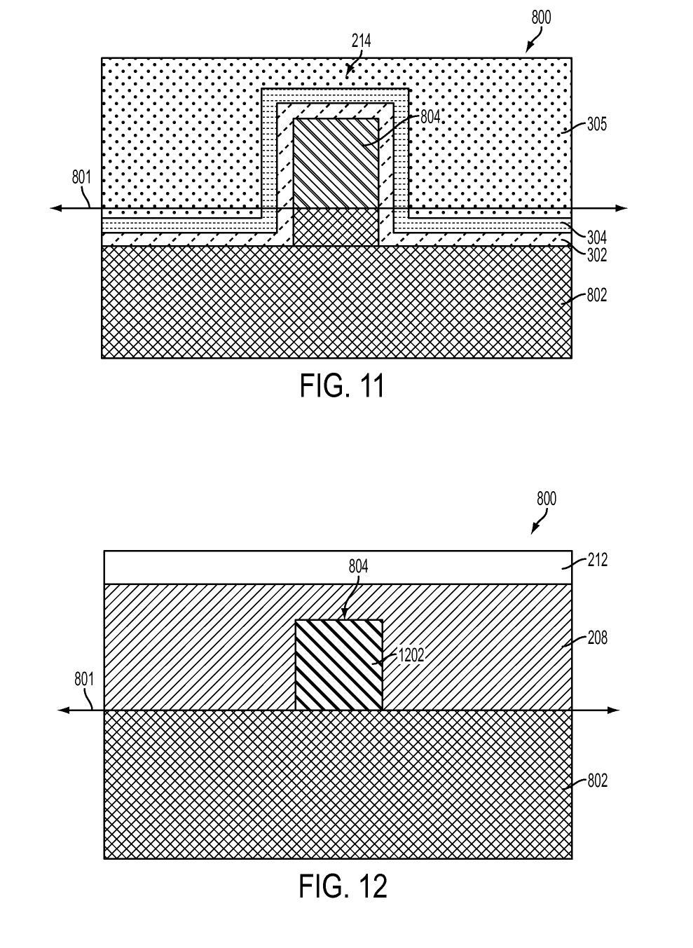

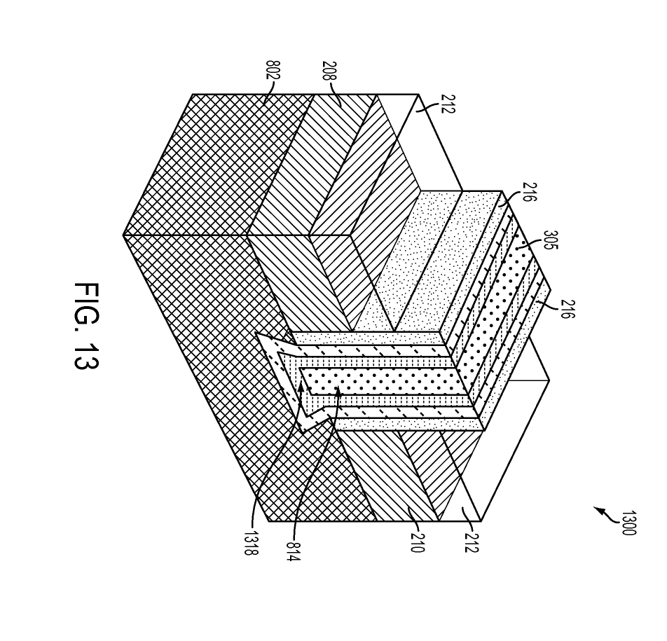

FIG. 9 illustrates a front view of the device 800. In this regard, a plane 801 is defined by where the source and drain regions 208 and 210 contact the insulator layer 802. The recessed region 818 includes sidewalls 806 that intersect the bottom surface 808. The bottom surface 808 and the plane 801 define a depth (d) where the bottom surface of the recessed region 818 and a portion of the gate stack 214 is arranged below the plane 801. FIG. 10 illustrates a cut-away view of the device 800 along the line 10 of FIG. 8 showing the fin 804 arranged on the insulator layer 802. FIG. 11 illustrates a cut-away view of the device 800 along the line 11 of FIG. 8. FIG. 12 illustrates a cut-away view of the device 800 along the line 12 of FIG. 8. FIG. 12 illustrates a source region 1202 of the fin 804 that may include a doped semiconductor material.

FIG. 13 illustrates a perspective view of another alternate embodiment of a FET device 1300. The device 1300 is similar to the device 800 described above in that the device 1300 is formed on an SOI substrate 802. However, the device 1300 includes a recessed region 1318 partially defined by the SOI substrate 802 that has sloped sidewalls that is similar to the recessed region 518 (of FIG. 5) described above. In some embodiments, portions of the gate stack 214 may conform to the opposing facing sides of the spacers 216 (Not shown in FIG. 13 for illustrative clarity).

The embodiments described herein offer finFET devices having gates that extend below source and drain regions of the FET devices. These embodiments provide a reduction in source-to-drain leakage current and allow a reduction in dopant concentration in the substrate and/or punch-through stopper regions.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

The flow diagrams depicted herein are just one example. There may be many variations to this diagram or the steps (or operations) described therein without departing from the spirit of the invention. For instance, the steps may be performed in a differing order or steps may be added, deleted or modified. All of these variations are considered a part of the claimed invention.

While the preferred embodiment to the invention had been described, it will be understood that those skilled in the art, both now and in the future, may make various improvements and enhancements which fall within the scope of the claims which follow. These claims should be construed to maintain the proper protection for the invention first described.

What is claimed is:

1. A field effect transistor device comprising:
a bulk semiconductor substrate;
a fin arranged on the bulk semiconductor substrate, the fin including a source region, a drain region, and a channel region;
a first shallow trench isolation (STI) region arranged on a portion of the bulk semiconductor substrate adjacent to the fin;
a first recessed region partially defined by the first STI region and the channel region of the fin; and
a gate stack arranged over the channel region of the fin, wherein a portion of the gate stack is partially disposed in the first recessed region.

2. The device of claim 1, further comprising:
a second STI region arranged on a portion of the bulk semiconductor substrate adjacent to the fin;
a second recessed region partially defined by the second STI region and the channel region of the fin, wherein a portion the gate stack is disposed in the second recessed region.

3. The device of claim 1, wherein the bulk semiconductor substrate includes a silicon material.

4. The device of claim 1, wherein the fin includes a silicon material.

5. The device of claim 1, wherein the device includes a source region comprising the source region of the fin and an epitaxially grown semiconductor material arranged over the source region of the fin.

6. The device of claim 1, wherein the device includes a drain region comprising the drain region of the fin and an epitaxially grown semiconductor material arranged over the drain region of the fin.

7. A field effect transistor device comprising:
a bulk semiconductor substrate;
a fin arranged on the bulk semiconductor substrate, the fin including a source region, a drain region, and a channel region;
a first shallow trench isolation (STI) region arranged on a portion of the bulk semiconductor substrate adjacent to the fin;
a first recessed region partially defined by the first STI region and the channel region of the fin, the first recessed region including a bottom surface and opposing sidewalls arranged adjacent to the bottom surface, each opposing sidewall defining an oblique angle with the bottom surface; and
a gate stack arranged over the channel region of the fin, wherein a portion of the gate stack is partially disposed in the first recessed region.

8. The device of claim 7, further comprising:
a second STI region arranged on a portion of the bulk semiconductor substrate adjacent to the fin;
a second recessed region partially defined by the second STI region and the channel region of the fin, the second recessed region including a bottom surface and opposing sidewalls arranged adjacent to the bottom surface, each opposing sidewall defining an oblique angle with the bottom surface wherein a portion the gate stack is disposed in the second recessed region.

9. The device of claim 7, wherein the bulk semiconductor substrate includes a silicon material.

10. The device of claim 7, wherein the fin includes a silicon material.

11. The device of claim 7, wherein the device includes a source region comprising the source region of the fin and an epitaxially grown semiconductor material arranged over the source region of the fin.

12. The device of claim 7, wherein the device includes a drain region comprising the drain region of the fin and an epitaxially grown semiconductor material arranged over the drain region of the fin.

13. A field effect transistor device comprising:
a silicon-on-insulator (SOI) substrate an insulator layer;
a fin arranged on the insulator layer, the fin including a source region, a drain region, and a channel region;
a first recessed region partially defined by the insulator layer and the channel region of the fin; and
a gate stack arranged over the channel region of the fin, wherein a portion of the gate stack is partially disposed in the first recessed region.

14. The device of claim 13, further comprising a second recessed region partially defined by the second insulator layer and the channel region of the fin, wherein a portion the gate stack is disposed in the second recessed region.

15. The device of claim 13, wherein the fin includes a silicon material.

16. The device of claim 13, wherein the device includes a source region comprising the source region of the fin and an epitaxially grown semiconductor material arranged over the source region of the fin.

17. The device of claim 13, wherein the device includes a drain region comprising the drain region of the fin and an epitaxially grown semiconductor material arranged over the drain region of the fin.

18. The device of claim 13, wherein the first recessed region includes a bottom surface and opposing sidewalls arranged adjacent to the bottom surface, each opposing sidewall defining an oblique angle with the bottom surface.

19. The device of claim 14, wherein the second recessed region includes a bottom surface and opposing sidewalls arranged adjacent to the bottom surface, each opposing sidewall defining an oblique angle with the bottom surface.

20. The device of claim 12, wherein the SOI substrate includes a semiconductor material arranged on the insulator layer.
